(19) United States
(12) Patent Application Publication
(10) Pub. No.: US 2013/0284266 A1
(43) Pub. Date: Oct. 31, 2013

(54) ELECTRONIC DEVICE AND MANUFACTURING METHOD THEREOF

(71) Applicant: ASAHI GLASS COMPANY, LIMITED, Chiyoda-ku (JP)

(72) Inventors: Satoshi TAKEDA, Chiyoda-ku (JP); Kazuo Yamada, Chiyoda-ku (JP); Toshihiro Takeuchi, Chiyoda-ku (JP); Yoko Mitsui, Chiyoda-ku (JP); Hiroyuki Yamamoto, Chiyoda-ku (JP)

(21) Appl. No.: 13/928,679

(22) Filed: Jun. 27, 2013

Related U.S. Application Data
(63) Continuation of application No. PCT/JP2011/078773, filed on Dec. 13, 2011.

(30) Foreign Application Priority Data
Dec. 27, 2010 (JP) 2010-291039

(51) Int. Cl. H01L 31/0203

(52) U.S. Cl. CPC H01L 31/0203
USPC 136/259; 438/64

(57) ABSTRACT

An electronic device 1 includes a first glass substrate 2, a second glass substrate 3, and an electronic element part 4 provided between these glass substrates 2, 3. The electronic element part 4 provided between the first and second glass substrates 2, 3 is sealed with a sealing layer 9 made up of a molten fixed layer of a sealing glass material having an electromagnetic wave absorption ability. At least one of the first and second glass substrates 2, 3 is made up of a chemically tempered glass having a surface compressive stress value of 900 MPa or less.

### CROSS-REFERENCE TO RELATED APPLICATIONS

This application is a continuation of prior International Application No. PCT/JP2011/078773, filed on Dec. 13, 2011 which is based upon and claims the benefit of priority from Japanese Patent Application No. 2010-291039, filed on Dec. 27, 2010; the entire contents of all of which are incorporated herein by reference.

### FIELD

The present invention relates to an electronic device and a manufacturing method thereof.

### BACKGROUND

In solar cells such as a thin-film silicon solar cell, a compound semiconductor solar cell, and a dye sensitized solar cell, it is studied to apply a glass package in which a battery element (photoelectric conversion element) is sealed with two pieces of glass substrates. In flat panel displays (FPD) such as an organic EL display (Organic Electro-Luminescence Display: OELD), a field emission display (FED), a plasma display panel (PDP), and a liquid crystal display (LCD), a structure is applied in which an element glass substrate where a display element is formed and a sealing glass substrate are disposed to face, and the display element is sealed with a glass package in which a gap between these two glass substrates are sealed.

It is required to enhance safety, reliability, and so on for the glass package applied to the solar cell, the FPD, and so on. In particular, the solar cell is provided at outside, and therefore, it is required to endure impacts such as wind pressure and hail for a long period of time. Therefore, it is proposed to apply a tempered glass for the glass substrate constituting the solar cell to correspond to the point as stated above. It has been proposed to use a chemically tempered glass as a transparent substrate forming a transparent electrode constituting a battery unit of the thin-film silicon solar cell and an amorphous silicon layer. It has been proposed that, about a solar cell glass substrate (cover glass) in which a degree of strengthening of a physically tempered glass is made to be semi-tempered state, and the thin-film silicon solar cell using the above glass substrate.

However, the battery unit formed on the glass substrate made up of the tempered glass is sealed with a resin-based adhesive and adhesive sheet in any of the solar cells, and therefore, temporal deterioration caused by moisture is inevitable. It is essential to improve not only impact resistance but also moisture resistance and weather resistance in the solar cell provided at outside. Strength of the tempered glass is lowered in Reference 3 for easy to cut in a manufacturing process of the solar cell, and therefore, it cannot be said to be enough as for the reliability, the safety, and so on for impact.

It has been known that a display structure is disposed between a glass vessel and a rear plate, and laser light is irradiated at a sealing glass disposed between outer peripheral parts of the glass vessel and the rear plate to form an image display device in which the outer peripheral part is sealed with a sealing layer (sealing glass layer) being a melted and solidified layer of a sealing glass. It has been proposed that, for example, the glass vessel is constituted by the tempered glass so as to suppress fractures of the glass vessel caused by local heating. It has been known that a photoelectric conversion device including a photoelectric conversion body disposed between a light transmissive substrate and a supporting substrate, and a sidewall part surrounding the photoelectric conversion body and bonding the light transmissive substrate and the supporting substrate. The sidewall part includes a bonding part made up of a sealing layer formed by irradiating the laser light to the sealing glass. It has been proposed that the tempered glass may be used for the light transmissive substrate as an action for hailfall.

When the local heating by the laser light on is applied to seal between the two pieces of glass substrates, it is possible to suppress thermal effect on electronic element parts such as the photoelectric conversion body and the display structure. At the same time, laser sealing is a process locally performing rapid heating and cooling of the sealing glass, and therefore, residual stress is easy to be generated at an adhesive interface between the sealing layer and the glass substrate and at a neighboring part thereof. On the other hand, a compressive stress is generated at a surface of the chemically tempered glass based on ion-exchange, and a tension stress is generated inside thereof so as to match with the surface compressive stress. There are possibilities in which cracks and fractures occur at the chemically tempered glass and the sealing layer at the laser sealing time, or adhesive strength and adhesive reliability between the chemically tempered glass and the sealing glass layer are deteriorated resulting that the residual stress generated at the adhesive interface and at the neighboring part thereof by the laser sealing is added to the stresses generated at the surface and inside of the chemically tempered glass.

### SUMMARY

An object of the present invention is to provide an electronic device and a manufacturing method thereof enabling to improve moisture resistance, weather resistance, and so on of a glass package using a chemically tempered glass, to suppress occurrences of cracks and fractures at an adhesive interface between the chemically tempered glass and a sealing layer and at a neighboring part thereof, and to increase sealing property and sealing reliability of the glass package using the chemically tempered glass.

An electronic device according to the present invention includes: a first glass substrate having a first surface including a first sealing region; a second glass substrate having a second surface including a second sealing region corresponding to the first sealing region, and disposed with a predetermined gap above the first glass substrate such that the second surface faces the first surface; an electronic element part provided between the first glass substrate and the second glass substrate; and a sealing layer formed between the first sealing region of the first glass substrate and the second sealing region of the second glass substrate to seal the electronic element part, and made up of a molten fixed layer of a sealing glass material having an electromagnetic wave absorption ability, wherein at least one of the first glass substrate and the second glass substrate is made up of a chemically tempered glass having a surface compressive stress value of 900 MPa or less.

A manufacturing method of an electronic device according to the present invention, includes: preparing a first glass substrate having a first surface including a first sealing region; preparing a second glass substrate having a second surface including a second sealing region corresponding to the first sealing region and a sealing material layer formed on the second sealing region and made up of a baked layer of a sealing glass material having an electromagnetic wave absorption ability; laminating the first glass substrate and the second glass substrate via the sealing material layer while facing the first surface and the second surface; and forming a sealing layer sealing an electronic element part provided between the first glass substrate and the second glass substrate by irradiating an electromagnetic wave and locally heating the sealing material layer through the first glass substrate or the second glass substrate to melt and solidify the sealing material layer, wherein at least one of the first glass substrate and the second glass substrate is made up of a chemically tempered glass having a surface compressive stress value of 900 MPa or less.

In an electronic device and a manufacturing method thereof according to the present invention, a gap between a first glass substrate and a second glass substrate constituting a glass package is sealed with a sealing glass material, and at least one of the first and second glass substrates is constituted by a chemically tempered glass of which surface compressive stress value is 900 MPa or less. Accordingly, it becomes possible to enhance a sealing property and sealing reliability of the glass package using the chemically tempered glass while improving reliability for external impact and so on, moisture resistance, weather resistance and so on of the electronic device in which an electronic element part is sealed with the glass package.

### BRIEF DESCRIPTION OF DRAWINGS

FIG. 1 is a sectional view illustrating an electronic device according to an embodiment of the present invention.

FIG. 2 is a sectional view illustrating a first configuration example of an electronic element part in the electronic device illustrated in FIG. 1.

FIG. 3 is a sectional view illustrating a second configuration example of the electronic element part in the electronic device illustrated in FIG. 1.

FIG. 4 is a sectional view illustrating a third configuration example of the electronic element part in the electronic device illustrated in FIG. 1.

FIG. 5 is a sectional view illustrating a fourth configuration example of the electronic element part in the electronic device illustrated in FIG. 1.

FIG. 6 is a sectional view illustrating a fifth configuration example of the electronic element part in the electronic device illustrated in FIG. 1.

FIG. 7A to FIG. 7D are sectional views illustrating a manufacturing process of the electronic device according to an embodiment of the present invention.

FIG. 8 is a plan view illustrating a first glass substrate used in the manufacturing process of the electronic device illustrated in FIG. 7A to FIG. 7D.

FIG. 9 is a sectional view along an A-A line in FIG. 8.

FIG. 10 is a plan view illustrating a second glass substrate used in the manufacturing process of the electronic device illustrated in FIG. 7A to FIG. 7D.

FIG. 11 is a sectional view along an A-A line in FIG. 10.

### DETAILED DESCRIPTION

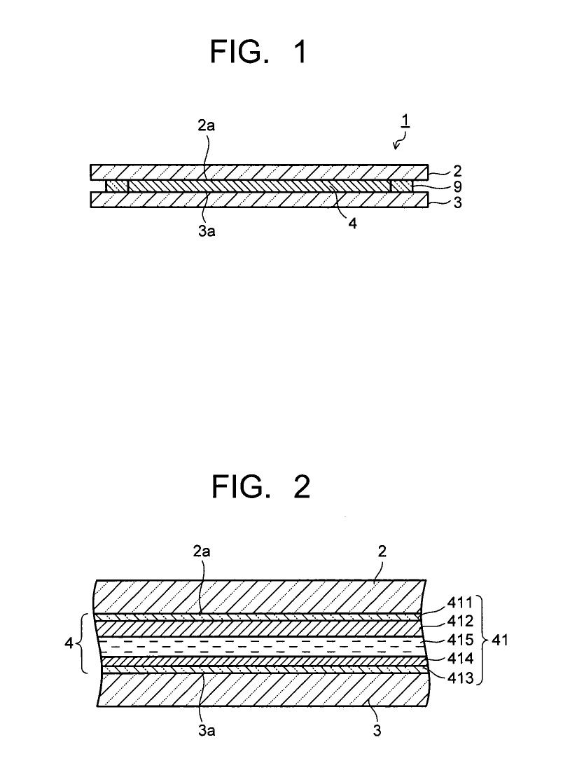

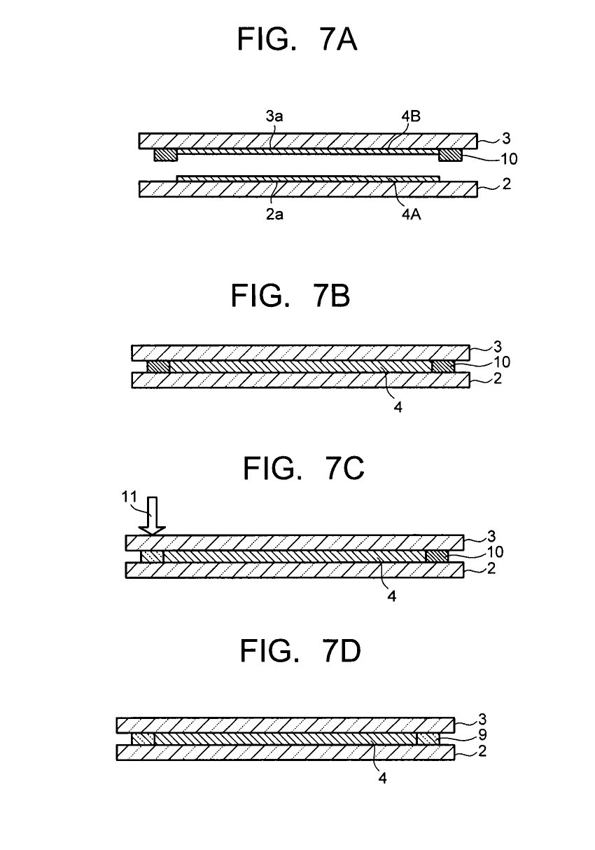

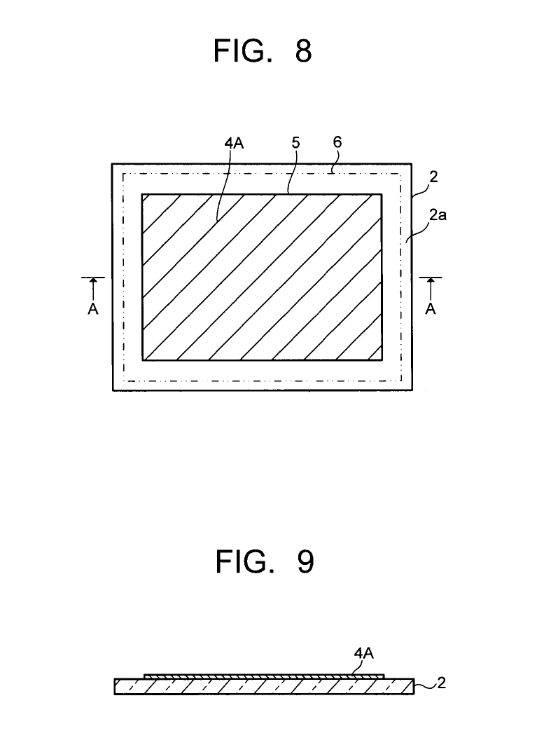

Hereinafter, embodiments of the present invention will be described with reference to the drawings. FIG. 1 is a view illustrating an electronic device according to an embodiment of the present invention. FIG. 2 to FIG. 6 are views illustrating configuration examples of an electronic element part in the electronic device illustrated in FIG. 1. FIG. 7A to FIG. 7D are views illustrating a manufacturing process of the electronic device according to an embodiment of the present invention. FIG. 8 to FIG. 11 are views illustrating configurations of a first and a second glass substrate used for the manufacturing process of the electronic device.

An electronic device 1 illustrated in FIG. 1 is the one constituting solar cells such as a thin-film silicon solar cell, a compound semiconductor solar cell, a dye sensitized solar cell, and an organic solar cell, or FPDs such as an OELD, an FED, a PDP, and an LCD, and a lighting device (OEL lighting and so on) using a light-emitting element such as an OEL element. The electronic device 1 includes a first glass substrate 2 and a second glass substrate 3 disposed to face with a predetermined gap.

An electronic element part 4 in accordance with the electronic device 1 is provided between a surface 2a of the first glass substrate 2 and a surface 3a of the second glass substrate 3 facing thereto. The electronic element part 4 includes, for example, a solar cell element (photoelectric conversion element) for the solar cell, an OEL element for the OELD and OEL lighting, a plasma light-emitting element for the PDP, and a liquid crystal display element for the LCD. The electronic element part 4 including the solar cell element, the light-emitting element, the display element, and so on has various publicly known structures. The electronic device 1 according to this embodiment is not limited to an element structure of the electronic element part 4.

An example of a structure of a dye sensitized solar cell element 41 is illustrated in FIG. 2 as a first configuration example of the electronic element part 4. In the dye sensitized solar cell element 41 illustrated in FIG. 2, a semiconductor electrode (photoelectrode/anode) 412 having sensitizing dye is provided at the surface 2a of the first glass substrate 2 to be mainly an irradiation surface of solar light via a transparent conducting film 411 made up of indium tin oxide (ITO), fluorine-doped tin oxide (FTO) and so on. A counter electrode (cathode) 414 is provided at the surface 3a of the second glass substrate 3 facing the surface 2a of the first glass substrate 2 via a transparent conducting film 413 similarly made up of ITO, FTO, and so on.

The semiconductor electrode 412 is made up of metal oxides such as titanium oxide, zirconium oxide, niobium oxide, tantalum oxide, zinc oxide. The semiconductor electrode 412 is constituted by a porous film of the metal oxide, and the sensitizing dye is absorbed inside thereof. For example, a metal complex dye such as a ruthenium complex dye, an osmium complex dye, and an organic dye such as a cyanine dye, a merocyanine dye, a triphenylmethane dye are used as the sensitizing dye. The counter electrode 414 is made up of a thin film of platinum, gold, silver, or the like. An electrolyte 415 is sealed between the first glass substrate 2 and the second glass substrate 3, and the dye sensitized solar cell element 41 is constituted by these components.

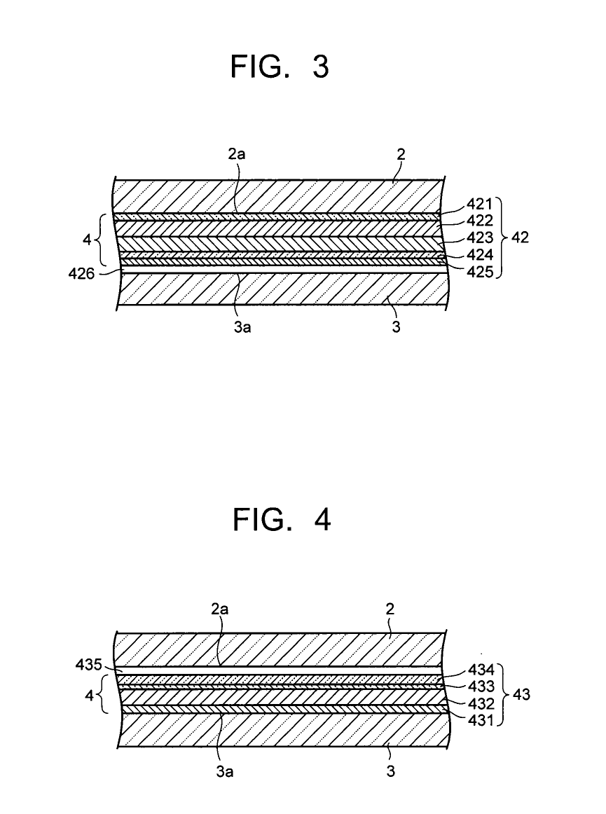

An example of a structure of a tandem thin-film silicon solar cell element 42 is illustrated in FIG. 3 as a second configuration example of the electronic element part 4. The tandem thin-film silicon solar cell element 42 illustrated in FIG. 3 includes a first transparent electrode 421, an amorphous silicon photoelectric conversion layer 422, a crystalline silicon photoelectric conversion layer 423, a second transparent electrode 424, a back electrode 425 sequentially provided on the surface 2a of the first glass substrate 2 to be an irradiation surface of solar light. The transparent electrodes 421, 424 are made up of SnO₂, ZnO, ITO, and so on, and the back electrode 425 is made up of Ag, and so on.

The amorphous silicon photoelectric conversion layer 422 has a p-type amorphous silicon film, an i-type amorphous silicon film, and an n-type amorphous silicon film. The crystalline silicon photoelectric conversion layer 423 has a p-type polycrystalline silicon film, an i-type polycrystalline silicon film, and a n-type polycrystalline silicon film. A transparent intermediate layer is provided between the amorphous silicon photoelectric conversion layer 422 and the crystalline silicon photoelectric conversion layer 423 according to need. A resin and so on are filled into a void 426 between the tandem thin-film silicon solar cell element 42 and the first glass substrate 2 according to need.

An example of a structure of a compound semiconductor solar cell element 43 is illustrated in FIG. 4 as a third configuration example of the electronic element part 4. The compound semiconductor solar cell element 43 illustrated in FIG. 4 includes a back electrode 431, a light absorption layer 432 made up of a compound semiconductor film, a buffer layer 433, and a transparent electrode 434 sequentially provided on the surface 3a of the second glass substrate 3 as an element glass substrate. The back electrode 431 is made up of a metal such as Mo. The transparent electrode 434 is made up of SnO₂, ZnO, ITO, and so on.

As a compound semiconductor constituting the light absorption layer 432, Cu (In, Ga)Se₂ (CIGS), Cu (In, Ga)(Se, S)₂ (CIGSS) CuInS₂ (CIS), and so on are used. An anti-reflection layer is provided on the transparent electrode 434 according to need. A resin and so on are filled into a void 435 between the compound semiconductor solar cell element 43 and the first glass substrate 2 to be the irradiation surface of solar light according to need.

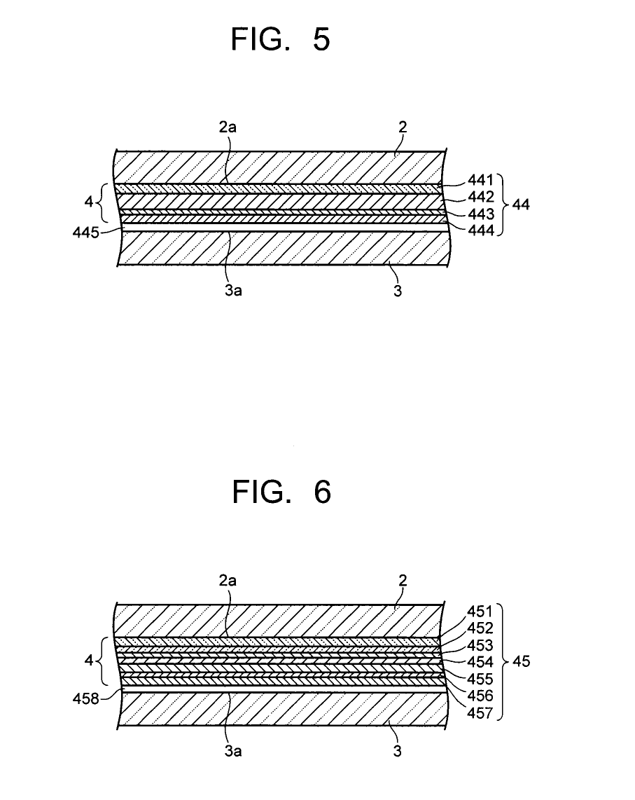

Another example of a structure of a compound semiconductor solar cell element 44 is illustrated in FIG. 5 as a fourth configuration example of the electronic element part 4. The compound semiconductor (CdTe) solar cell element 44 illustrated in FIG. 5 includes a transparent n-type CdS film 441, a p-type CdTe film 442, a Cu-containing carbon electrode 443, and an In-containing Ag electrode 444 sequentially provided on the surface 2a of the first glass substrate 2 to be the irradiation surface of solar light. A resin and so on are filled into a void 445 between the CdTe solar cell element 44 and the second glass substrate 3 according to need.

An example of a structure of an organic solar cell element 45 is illustrated in FIG. 6 as a fifth configuration example of the electronic element part 4. The organic solar cell element (organic thin-film solar cell element) 45 illustrated in FIG. 6 includes a transparent electrode 451, a buffer layer 452, a p-type organic semiconductor layer 453 made up of zinc phthalocyanine (ZnPc) and so on, an i-type organic semiconductor layer 454 made up of a mixture and so on of ZnPc and fullerene (C60), an n-type semiconductor layer 455 made up of fullerene (C60) and so on, a buffer layer 456, and a back electrode (metal electrode) 457 sequentially provided on the surface 2a of the first glass substrate 2 to be the irradiation surface of solar light. A resin and so on are filled into a void 458 between the organic solar cell element 45 and the second glass substrate 3 according to need.

An element film and an element structure based on the element film constituting the electronic element part 4 are formed at least one of the surfaces 2a, 3a of the first and second glass substrates 2, 3. In the dye sensitized solar cell element 41 illustrated in FIG. 2, the element films are formed at the respective surfaces 2a, 3a of the first and second glass substrates 2, 3. In each of the thin-film silicon solar cell element 42 illustrated in FIG. 3, the compound semiconductor solar cell element 44 illustrated in FIG. 5, and the organic solar cell element 45 illustrated in FIG. 6, the element film is formed at the surface 2a of the first glass substrate 2. In the compound semiconductor solar cell element 43 illustrated in FIG. 4, the element film is formed at the surface 3a of the second glass substrate 3. In the OEL element applied to the OELD and OEL lightings and so on, the second glass substrate 3 is used as the element glass substrate, and the element structure is formed at the surface thereof. The first glass substrate 2 is used as a sealing member of the OEL element.

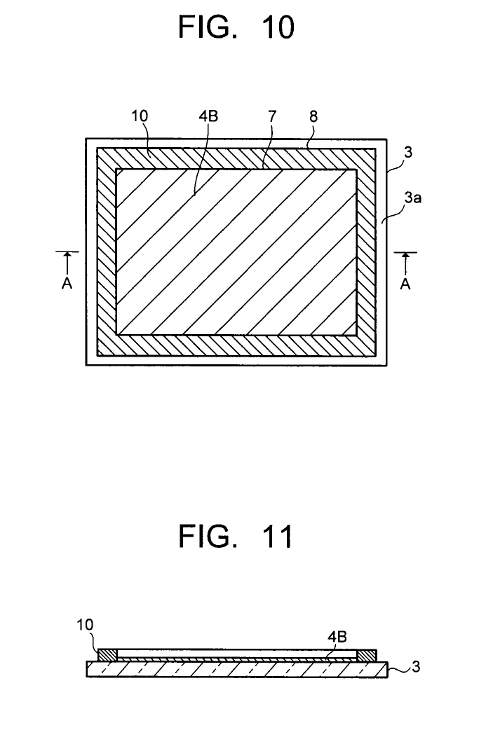

The surface 2a of the first glass substrate 2 used for the manufacturing of the electronic device 1 includes a first element region 5 where at least a part of the electronic element part 4 (4A) is formed and a first sealing region 6 disposed along an outer periphery of the first element region 5 as illustrated in FIG. 8 and FIG. 9. The first sealing region 6 is provided to surround the first element region 5. The surface 3a of the second glass substrate 3 includes a second element region 7 corresponding to the first element region 5 and a second sealing region 8 corresponding to the first sealing region 6 as illustrated in FIG. 10 and FIG. 11.

When the element film and so on are formed also at the surface 3a of the second glass substrate 3 as in the dye sensitized solar cell element 41 illustrated in FIG. 2, a part of the electronic element part 4 (4B) is formed at the second element region 7. When one glass substrate 2 (or 3) is used as the element glass substrate as the thin-film silicon solar cell element 42 illustrated in FIG. 3, the compound semiconductor solar cell elements 43, 44 illustrated in FIG. 4 and FIG. 5, the organic solar cell element 45 illustrated in FIG. 6, and the light-emission element such as the OEL element, the second element region 7 of the other glass substrate 3 (or 2) becomes a facing region of the first element region 5. The first and second sealing regions 6, 8 each are a formation region of a sealing layer. Further, the second sealing region 8 becomes a formation region of a sealing material layer.

The first glass substrate 2 and the second glass substrate 3 are disposed with a predetermined gap so as to face the surfaces 2a, 3a where the structures 4A, 4B of the electronic element part 4 are formed. The gap between the first glass substrate 2 and the second glass substrate 3 is sealed with a sealing layer 9. The sealing layer 9 is formed between the sealing region 6 of the first glass substrate 2 and the sealing region 8 of the second glass substrate 3 to seal the electronic element part 4. The electronic element part 4 is hermetically sealed by a glass package constituted by the first glass substrate 2, the second glass substrate 3, and the sealing layer 9.

When the dye sensitized solar cell element 41 and so on are applied as the electronic element part 4, the electronic element part 4 is disposed at a whole of the gap between the first glass substrate 2 and the second glass substrate 3. When the thin-film silicon solar cell element 42, the compound semiconductor solar cell elements 43, 44, the organic solar cell element 45, the OEL element, and so on are applied as the electronic element part 4, a void remains at a part between the first glass substrate 2 and the second glass substrate 3. The void as stated above may be as it is, or a transparent resin and so on may be filled therein. The transparent resin may be adhered to the glass substrates 2, 3 or may be just in contact with the glass substrates 2, 3.

In the electronic device 1 according to the embodiment, at least one of the first glass substrate 2 and the second glass substrate 3 is constituted by a chemically tempered glass. For example, it is preferable to constitute the following by the chemically tempered glass: a light-receiving surface of the solar light in case when the electronic element part 4 is the solar cell element; a display surface for the FPD; and the first glass substrate 2 (or the second glass substrate 3) to be a light-emission surface for the OEL lighting. Both of the first glass substrate 2 and the second glass substrate 3 may be constituted by the chemically tempered glasses. At least one of the first glass substrate 2 and the second glass substrate 3 constituting the glass package is constituted by the chemically tempered glass, and thereby, it becomes possible to improve a panel strength of the electronic device 1 for external impact and so on.

The chemically tempered glass is the one in which an ion-exchange layer is formed at a surface region of a glass plate to thereby generate a compressive stress at the surface to strengthen it. The ion-exchange layer is a layer in which, for example, sodium ions in the glass plate are ion-exchanged with potassium ions of which ionic radius is larger. The chemical tempering can be applied to a glass plate of which sheet thickness is thinner compared to a physical tempering, and in addition, it is possible to obtain the strength equivalent to the physical tempering. Accordingly, the chemically tempered glass substrate is applied to at least one of the first and second glass substrates 2, 3, and thereby, it becomes possible to enable reduction in weight of the electronic device 1 in addition to improve the panel strength for the impact and so on of the electronic device 1.

A sheet thickness of the chemically tempered glass substrate is preferable to be made thin within a range capable of maintaining impact resistance and so on. Specifically, the sheet thickness of the chemically tempered glass substrate is preferable to be 4 mm or less. When the sheet thickness of the chemically tempered glass substrate exceeds 4 mm, there is a possibility in which an effect of weight reduction of the electronic device 1 such as the solar cell, the FPD cannot be fully obtained. It is more preferable that the sheet thickness of the chemically tempered glass substrate is set to be 2 mm or less to enable both the improvement of the panel strength and the weight reduction by the chemically tempered glass substrate. A lower limit value of the sheet thickness of the chemically tempered glass substrate is not particularly limited, but it is preferable to be set at 0.1 mm or more in consideration of practical functions and so on of the electronic device 1.

When one of the first and second glass substrates 2, 3 is constituted by the chemically tempered glass, it is possible to constitute the other by a soda lime glass, a alkali-free glass, and so on. It is possible to apply various publicly known compositions to the soda lime glass and the alkali-free glass. It is preferable to constitute the other glass substrate by the soda lime glass so as to improve the reliability of the electronic device 1. Note that one of the glass substrates 2, 3 is constituted by the chemically tempered glass, and therefore, it is possible to constitute the other glass substrate by the alkali-free glass.

Further in the electronic device 1 according to this embodiment, a sealing glass material having electromagnetic wave absorption ability is applied to the sealing layer 9 sealing between the glass substrates 2, 3 in which at least one of them is constituted by the chemically tempered glass. Namely, a frame-shaped sealing material layer 10 made up of a baked layer of the sealing glass material as illustrated in FIG. 10 and FIG. 11 is formed at the sealing region 8 of the second glass substrate 3 used for the manufacturing of the electronic device 1. The sealing material layer 10 formed at the sealing region 8 of the second glass substrate 3 is melted at a heating process by a later-described electromagnetic wave and fixed to the sealing region 6 of the first glass substrate 2. As stated above, the gap between the first glass substrate 2 and the second glass substrate 3 is sealed with the sealing layer 9 made up of a molten fixed layer of the sealing glass material.

The glass package is constituted by the first and second glass substrates 2, 3 and the sealing layer 9 made up of the molten fixed layer of the sealing glass material, and thereby, it is possible to suppress entering of moisture and so on into the glass package for a long period of time with high repeatability. Namely, it is possible to improve the moisture resistance, the weather resistance, and so on of the glass package. The electronic element part 4 is sealed with the glass package as stated above, and thereby, it becomes possible to suppress deterioration of the electronic element part 4 for a long period of time with high repeatability. Accordingly, it is possible to provide the electronic device 1 capable of stably maintaining properties of the electronic element part 4, for example, a power generation property for the solar cell element for a long period of time.

Incidentally, when at least one of the first glass substrate 2 and the second glass substrate 3 is constituted by the chemically tempered glass, there are possibilities in which cracks and fractures occur at an adhesive interface between the glass substrate made up of the chemically tempered glass and the sealing layer 9 and at a neighboring part thereof at a sealing time by the electromagnetic wave, and adhesive strength and adhesive reliability between the chemically tempered glass substrate and the sealing glass layer may deteriorate. As stated above, the compressive stress is generated at the surface of the chemically tempered glass substrate based on the ion-exchange. On the other hand, the tension stress is generated based on the rapid heating and cooling process at the sealing layer 9 to which the local heating by the electromagnetic wave is applied. Namely, when the sealing material layer 10 is heated and melted by irradiating the electromagnetic wave, the sealing glass material is melted and expanded at the irradiation time of the electromagnetic wave, and is rapidly cooled and shrinks at a time when the irradiation of the electromagnetic wave is finished. In the heating by the electromagnetic wave, not only a heating speed but also a cooling speed are fast, and therefore, the sealing glass material is solidified before it shrinks enough. Accordingly, the tension stress is generated at the sealing layer 9.

Stress directions of the surface stress of the chemically tempered glass substrate and the stress generated inside the sealing layer 9 are opposite, and therefore, the cracks and fractures occur easily at the adhesive interface between the chemically tempered glass substrate and the sealing layer 9 and at the neighboring part thereof at the sealing time by the electromagnetic wave. The cracks and fractures occurred at the adhesive interface and at the neighboring part thereof become a cause of a sealing failure of the glass package using the chemically tempered glass substrate. Further, the adhesive strength is easy to be lowered and there is a possibility that the reliability is lost even if the adhesion can be done because the residual stress increases resulting that the directions of the stresses between the chemically tempered glass substrate and the sealing layer 9 are opposite. When the sealing process is performed while increasing power of the electromagnetic wave to improve the adhesive strength, the residual stress further increases, and the fractures and so on are easy to occur at the chemically tempered glass substrate and the sealing layer 9.

Accordingly, the chemically tempered glass of which surface compressive stress value (CS value) is 900 MPa or less is applied to at least one of the first glass substrate 2 and the second glass substrate 3 in the electronic device 1 according to the present embodiment. The surface compressive stress (CS) is a stress generated by exchanging alkali metal ions in the glass with the alkali metal ions of which ion radius is larger, and is a value representing a degree of glass surface strength. When the CS value of the chemically tempered glass is too high, repulsion with the tension stress generated inside the sealing layer 9 becomes large. Further, when the CS value is high, a density of the exchange ion becomes high. Accordingly, wettability and reactivity of the sealing glass deteriorate. The adhesive failure and the cracks, fractures, and so on at the adhesive time are thereby easy to occur.

According to the chemically tempered glass of which CS value is 900 MPa or less, the repulsion with the tension stress generated inside the sealing layer 9 is reduced, further the wettability and the reactivity of the sealing glass can be increased. The adhesive failure between the chemically tempered glass substrate and the sealing layer 9, and the occurrences of the cracks and fractures at the adhesive interface and at the neighboring part thereof can be suppressed even when the sealing is performed by applying the rapid heating and cooling process by the electromagnetic wave. Namely, it becomes possible to seal the gap between the first glass substrate 2 and the second glass substrate 3 in which at least one of them is constituted by the chemically tempered glass with the sealing layer 9 made up of the molten fixed layer of the sealing glass material having the electromagnetic wave absorption ability with high repeatability. In other words, the gap between the first glass substrate 2 and the second glass substrate 3 can be sealed with high repeatability by the process melting and solidifying the sealing material layer 10 by locally irradiating the electromagnetic wave.

The CS value of the chemically tempered glass is more preferable to be 700 MPa or less. The CS value is set to be 700 MPa or less, and thereby, it becomes possible to suppress the occurrences of the cracks and fractures at the adhesive interface between the chemically tempered glass substrate and the sealing layer 9 and at the neighboring part thereof with high repeatability. The adhesiveness and the adhesive reliability of the sealing layer 9 improve as the CS value of the chemically tempered glass is smaller, but functions as the chemically tempered glass substrate are lost if the CS value is too small. Namely, it becomes impossible to fully obtain the improvement effect of the impact resistance and the weight reduction effect of the electronic device 1. Accordingly, it is preferable that the CS value of the chemically tempered glass is 300 MPa or more. Further, the CS value of the chemically tempered glass is more preferable to be 500 MPa or more to improve the sealing property and the sealing reliability while enabling both the improvement in reliability and the weight reduction by the chemically tempered glass.

Further, a central tension stress value (CT value) of the chemically tempered glass constituting the glass substrates 2, 3 is preferable to be 70 MPa or less. The central tension stress (CT) is a stress generated inside the chemically tempered glass so as to match with the surface compressive stress (CS). The CT value (unit: MPa) of the chemically tempered glass is a value found by the following expression (1) from the CS value (unit: MPa), a depth of ion-exchange layer (DOL (unit: μm)), and a thickness of the glass substrate t (unit: μm).

CT=(CS×DOL)/(t−2DOL) (1)

When the sealing layer 9 is formed by irradiating the electromagnetic wave at the sealing material layer 10, the glass substrates 2, 3 are partially heated to be expanded as same as the sealing glass material. This partial expansion is frozen at the rapid cooling time, and therefore, the residual stress of the tension is generated at a neighboring part of the glass substrates 2, 3 to the sealing layer 9. When the central tension stress (CT) of the chemically tempered glass is too high, the tension stress (residual stress) generated at the formation time of the sealing layer 9 is added thereto, and thereby, the fractures of the chemically tempered glass are easy to occur when, for example, a thermal cycle is applied. This causes deterioration of the reliability of the glass package. Namely, when the CT value of the chemically tempered glass is too high, the reliability of the glass package for a thermal cycle test (TCT) deteriorates.

According to the chemically tempered glass of which CT value is 70 MPa or less, it is possible to suppress the fractures when the thermal cycle is applied even if the residual stress (tension stress) is added when the sealing layer 9 is formed. It becomes possible to improve the reliability (sealing reliability) of the glass package in which at least one of the glass substrates 2, 3 is constituted by the chemically tempered glass for the thermal cycle test (TCT) and so on. The CT value of the chemically tempered glass is more preferable to be 50 MPa or less. The CT value is set to be 50 MPa or less, and thereby, it is possible to further enhance the sealing reliability of the glass package. The CT value of the chemically tempered glass is a value determined by the CS value, the DOL, and the thickness of the glass substrate, and therefore, a lower limit value thereof is not particularly limited. However, it is practically preferable that the CT value is 1.5 MPa or more.

As stated above, the gap between the glass substrates 2,3 in which at least one of them is constituted by the chemically tempered glass is sealed with the sealing glass material having the electromagnetic wave absorption ability, and thereby, it is possible to improve the panel strength of the electronic device 1 for the external impact and so on while maintaining the moisture resistance and the weather resistance of the electronic device 1. Further, the chemically tempered glass of which CS value is 900 MPa or less and CT value is 50 MPa or less is used, and thereby, it is possible to enhance the sealing property and the sealing reliability of the glass package using the chemically tempered glass. It is thereby possible to provide the electronic device 1 capable of stably exhibiting the functions and properties for a long period of time.

Further, it is possible to enable both high strengthening and weight reduction of the electronic device 1. Accordingly, it is possible to provide the electronic device 1 excellent in the weather resistance and the impact resistance, having light weight and high reliability. When the electronic device 1 is the solar cell, it is possible to suppress the damage of the glass substrate 3 caused by the hail and so on, the deterioration and loss of the power generation property based on the damage, and to suppress the temporal deterioration of the power generation property caused by the moisture and so on, in addition to enabling the weight reduction of the device. Namely, it is possible to provide the solar cell capable of stably generating power under a severe environment for a long period of time. When the electronic device 1 is the FPD and so on, it is possible to enable the weight reduction of the device in addition to enhance the reliability and the safety. The glass package in which the chemically tempered glass is applied to at least one of the first and second glass substrates 2, 3 can be applied not only to the electronic device 1 but also to a sealing body of an electronic parts and a glass member (building material and so on) such as a double glass.

Next, a manufacturing process of the electronic device 1 according to the embodiment is described with reference to FIG. 7A to FIG. 7D. At first, a sealing glass material to be a formation material of the sealing layer 9 is prepared. The sealing glass material is the one in which an electromagnetic wave absorbing material and an inorganic filler such as a low-expansion filler are compounded according to need to a sealing glass made up of a low-melting glass. When a sealing glass in itself has the electromagnetic wave absorption ability such as a sealing glass having a blackish color tone, it is possible to constitute the sealing glass material by the sealing glass and the low-expansion filler added according to need without compounding the electromagnetic wave absorbing material. The sealing glass material may contain additives other than the above.

As the sealing glass (glass frit), for example, a bismuth-based glass, a tin-phosphate based glass, a vanadium-based glass, a lead-based glass, and so on are used. Among them, it is preferable to use the sealing glass made up of the bismuth-based glass and the tin-phosphate based glass in consideration of the adhesiveness for the glass substrates 2, 3 and the reliability thereof, further, effects for environment and human body, and so on. In particular, it is preferable to use the bismuth-based glass as the sealing glass in the sealing glass material sealing between the glass substrates 2, 3 in which at least one of them is constituted by the chemically tempered glass.

The bismuth-based glass (glass frit) is preferable to have a composition of Bi₂O₃ for 70 mass % to 90 mass %, ZnO for 1 mass % to 20 mass %, and B₂O₃ for 2 mass % to 12 mass % (basically, a total amount is set to be 100 mass %). Bi₂O₃ is a component forming a mesh of the glass. When a content of Bi₂O₃ is less than 70 mass %, a softening point of the low-melting glass becomes high, and sealing at a low temperature becomes difficult. When the content of Bi₂O₃ exceeds 90 mass %, it becomes difficult to be vitrified, and there is a tendency in which a thermal expansion coefficient becomes too high.

ZnO is a component lowering the thermal expansion coefficient and so on. When a content of ZnO is less than 1 mass %, the vitrification becomes difficult. When the content of ZnO exceeds 20 mass %, stability when a low-melting glass is molded is lowered, and devitrification is easy to occur. B₂O₃ is a component forming a skeletal structure of the glass and enlarging a range where the vitrification is possible. When a content of B₂O₃ is less than 2 mass %, the vitrification becomes difficult, and when it exceeds 12 mass %, it becomes difficult to seal at the low temperature even if a load is applied at the sealing time because the softening point becomes too high.

A glass transition point of the glass formed by the above-stated three components is low, and it is suitable for the sealing material for low temperature, but arbitrary components such as Al₂O₃, CeO₂, SiO₂, Ag₂O, MoO₃, Nb₂O₃, Ta₂O₅, Ga₂O₃, Sb₂O₃, Li₂O, Na₂O, K₂O, Cs₂O, CaO, SrO, BaO, WO₃, P₂O₅, SnOₓ (x is 1 or 2) may be contained. Note that when a content of the arbitrary components is too much, there are possibilities in which the devitrification occurs because the glass becomes unstable, and the glass transition point and the softening point increase, and therefore, it is preferable that a total content of the arbitrary components is set to be 30 mass % or less. The glass component in this case is adjusted such that the total amount of the basic components and the arbitrary components basically becomes 100 mass %.

The tin-phosphate based glass (glass frit) is preferable to have a composition of SnO for 55 mol % to 68 mol %, SnO₂ for 0.5 mol % to 5 mol %, and P₂O₅ for 20 mol % to 40 mol % (basically a total amount is set to be 100 mol %). SnO is a component to lower the melting point of the glass. When a content of SnO is less than 55 mol %, viscosity of the glass becomes high and a sealing temperature becomes too high. On the other hand, when it exceeds 68 mol %, it is not vitrified.

SnO₂ is a component to stabilize the glass. When a content of SnO₂ is less than 0.5 mol %, SnO₂ is separated and precipitated into the glass softened and melted at the sealing time, then fluidity is lost and the sealing workability deteriorates. When the content of SnO₂ exceeds 5 mol %, SnO₂ is easy to be precipitated during the low-melting glass is melted. P₂O₅ is a component to form a glass skeleton structure. When a content of P₂O₅ is less than 20 mol %, it is not vitrified, and when the content exceeds 40 mol %, there is a possibility in which deterioration of the weather resistance being a defect peculiar to the phosphate glass is incurred.

The glass transition point of the glass formed by the above-stated three components is low, and it is suitable for a low temperature sealing material, but a component forming the skeleton structure of the glass such as SiO₂ and components and so on stabilizing the glass such as ZnO, B₂O₃, Al₂O₃, WO₃, MoO₃, Nb₂O₅, TiO₂, ZrO₂, Li₂O, Na₂O, K₂O, Cs₂O, MgO, CaO, SrO, BaO may be contained as arbitrary components. Note that when a content of the arbitrary components is too much, there are possibilities in which the glass becomes unstable and devitrification may occur, and the glass transition point and the softening point increase, and therefore, it is preferable that a total content of the arbitrary components is set to be 30 mol % or less. The glass composition in this case is basically adjusted such that a total amount of the basic components and the arbitrary components becomes to be 100 mol %.

It is preferable to use at least one kind of metal selected from a group made up of Fe, Cr, Mn, Co, Ni and Cu, or a compound of an oxide and so on containing the above-stated metals as the electromagnetic wave absorbing material. The electromagnetic wave absorbing material may be a pigment other than these metals and metal oxides. A content of the electromagnetic wave absorbing material is preferable to be set within a range of 0.1 vol % to 10 vol % relative to the sealing glass material. When the content of the electromagnetic wave absorbing material is less than 0.1 vol %, there is a possibility in which the sealing material layer 10 cannot be fully melted at the irradiation time of the electromagnetic wave. When the content of the electromagnetic wave absorbing material exceeds 10 vol %, heat is locally generated in a vicinity of the interface with the second glass substrate 3, and there is a possibility in which the glass substrates 2, 3 and the sealing layer 9 are damaged, further fluidity of the sealing glass material at the melting time deteriorates to incur deterioration of adhesiveness with the first glass substrate 2.

It is preferable to use at least one kind selected from a group made up of silica, alumina, zirconia, zirconium silicate, aluminum titanate, mullite, cordierite, eucryptite, spodumene, zirconium phosphate based compound, tin oxide based compound, quartz solid solution, and mica as the low-expansion filler. As the zirconium phosphate based compound, (ZrO)₂P₂O₇, NaZr₂(PO₄)₃, KZr₂(PO₄)₃, Ca_{0.5}Zr₂(PO₄)₃, NbZr(PO₄)₃, Zr₂(WO₃)(PO₄)₂, a complex compound of these can be cited. The low-expansion filler has the thermal expansion coefficient lower than the sealing glass.

A content of the low-expansion filler is appropriately set so that the thermal expansion coefficient of the sealing glass material approximates to those of the glass substrates 2, 3. It is preferable that the low-expansion filler is to be contained within a range of 50 vol % or less relative to the sealing glass material though it depends on the thermal expansion coefficients of the sealing glass and the glass substrates 2, 3. When the content of the low-expansion filler exceeds 50 vol %, there is a possibility in which the fluidity of the sealing glass material deteriorates to incur the deterioration of the adhesive strength. The low-expansion filler is to be compounded according to need, and it is not necessarily to be compounded into the sealing glass material. Accordingly, the content of the low-expansion filler in the sealing glass material includes zero, but it is practically preferable to be set at 0.1 vol % or more. When the content of the low-expansion filler is less than 0.1 vol %, there is a possibility in which an effect adjusting the thermal expansion coefficient of the sealing glass material cannot be fully obtained.

A sealing process between the glass substrates 2, 3 by the sealing glass material having the electromagnetic wave absorption ability is performed by disposing the baked layer (sealing material layer 10) of the sealing glass material absorbing the electromagnetic wave of laser light, infrared light and so on between the sealing regions 6, 8, and locally heating it by irradiating the electromagnetic wave. According to the local heating by the electromagnetic wave, it is possible to suppress property deterioration of the electronic element part 4 by the sealing process compared to a case when a whole of the glass substrates 2, 3 having the electronic element part 4 (4A, 4B) is heated. The laser light, the infrared light, and so on are used as stated above as a heating source of the local heating. Hereinafter, the sealing process applying the local heating by the electromagnetic wave is described in detail.

At first, a sealing material paste is prepared by mixing the sealing glass material and a vehicle. The vehicle is the one in which a resin being a binder component is dissolved in a solvent. For example, organic resins such as a cellulose-based resin such as methyl cellulose, ethyl cellulose, carboxymethyl cellulose, oxyethyl cellulose, benzyl cellulose, propyl cellulose, nitro cellulose, and an acryl-based resin obtained by polymerizing one kind or more of acryl-based monomer such as methyl methacrylate, ethyl methacrylate, butyl methacrylate, 2-hydroxyethyl methacrylate, butyl acrylate, 2-hydroxyethyl acrylate are used as the resin for the vehicle. As the solvent, terpineol, butyl carbitol acetate, ethyl carbitol acetate, and so on are used for the cellulose-based resins, and methyl ethyl ketone, terpineol, butyl carbitol acetate, ethyl carbitol acetate, and so on are used for the acryl-based resin.

The sealing material paste is coated on the sealing region 8 of the second glass substrate 3, it is dried to form a coating layer of the sealing material paste. The sealing material paste is coated on the second sealing region 8 by applying, for example, a printing method such as a screen printing, and a gravure printing, or it is coated along the second sealing region 8 by using a dispenser and so on. The coating layer of the sealing material paste is preferable to be dried, for example, at a temperature of 120° C. or more for 10 minutes or more. A drying process is performed to remove the solvent in the coating layer. If the solvent remains in the coating layer, there is a possibility in which the binder component cannot be enough removed at the subsequent baking process.

Next, the sealing material layer 10 is formed by baking the coating layer of the sealing material paste. In the baking process, the coating layer is heated to a temperature of the glass transition point or less of the sealing glass (glass frit) being a major constituent of the sealing glass material to remove the binder component in the coating layer, and thereafter, it is heated to a temperature of the softening point or more of the sealing glass to melt the sealing glass and bake onto the glass substrate 3. As stated above, the sealing material layer 10 made up of the baked layer of the sealing glass material is formed at the surface 3a of the second glass substrate 3 as illustrated in FIG. 7A. The sealing material layer 10 may be formed at the sealing region 6 of the first glass substrate 2 depending on structures of the electronic device 1 and the electronic element part 4.

Next, the first glass substrate 2 and the second glass substrate 3 are laminated via the sealing material layer 10 to face the surfaces 2a, 3a thereof with each other as illustrated in FIG. 7B. Next, an electromagnetic wave 11 such as the laser light and the infrared light is irradiated on the sealing material layer 10 through the second glass substrate 3 (or the first glass substrate 2) as illustrated in FIG. 7C. When the laser light is used as the electromagnetic wave 11, the laser light is irradiated while scanning along the frame-shaped sealing material layer 10. The laser light is not particularly limited, and the laser lights from a semiconductor laser, a carbon dioxide gas laser, an excimer laser, a YAG laser, an HeNe laser, and so on are used. When the infrared light is used as the electromagnetic wave 11, it is preferable to selectively irradiate the infrared light to the sealing material layer 10 by, for example, masking a part other than a formation portion of the sealing material layer 10 with an infrared light reflective film and so on.

When the laser light is used as the electromagnetic wave 11, the sealing material layer 10 is sequentially melted from the part where the laser light scanning along the sealing material layer 10 is irradiated, rapidly cooled and solidified simultaneously with end of irradiation of the laser light, and fixed to the first glass substrate 2. The laser light is irradiated for all around the sealing material layer 10, and thereby, the sealing layer 9 sealing between the first glass substrate 2 and the second glass substrate 3 is formed as illustrated in FIG. 7D. When the infrared light is used as the electromagnetic wave 11, the sealing material layer 10 is locally heated and melted based on the irradiation of the infrared light, rapidly cooled and solidified simultaneously with end of irradiation of the infrared light, and fixed to the first glass substrate 2. As a result, the sealing layer 9 sealing between the first glass substrate 2 and the second glass substrate 3 is formed as illustrated in FIG. 7D.

A heating temperature of the sealing material layer 10 by the electromagnetic wave 11 is preferable to be set in a range of (T+100° C.) or more and (T+400° C.) or less relative to the softening temperature T (° C.) of the sealing glass. As stated above, the stress directions of the surface stress of the chemically tempered glass substrate and the stress generated at the sealing layer 9 are opposite, and therefore, there is a possibility in which the adhesive strength between the glass substrates 2, 3 and the sealing layer 9 is lowered if it is impossible to enough make the sealing material layer 10 flow because the heating temperature of the sealing material layer 10 is too low. Accordingly, it is preferable that the heating temperature of the sealing material layer 10 is set to be (T+100° C.) or more. On the other hand, when the heating temperature of the sealing material layer 10 exceeds (T+400° C.), the residual stress of tension in the sealing layer 9 becomes large, and the fractures and so on become easy to occur at the glass substrates 2, 3 and the sealing layer 9. The softening point of the sealing glass in the present description is defined by a fourth inflection point of an differential thermal analysis (DTA).

As stated above, when at least one of the first glass substrate 2 and the second glass substrate 3 is constituted by the chemically tempered glass, the adhesive failure is easy to occur between the chemically tempered glass substrate and the sealing layer 9 at the sealing time, and the cracks and the fractures are easy to occur at the adhesive interface and the neighboring part thereof caused by an interaction between the stress at the surface and inside of the chemically tempered glass and the residual stress generated when the sealing layer 9 is formed. It is effective to use the chemically tempered glass having the CS value of 900 MPa or less to address to the point as stated above. It is effective to use the chemically tempered glass having the CT value of 50 MPa or less to increase the reliability of the sealing part by the sealing glass material.

Further, when the local heating of the sealing glass material by the electromagnetic wave 11 is applied to the sealing of the glass package in which at least one of the first and second glass substrates 2, 3 is made up of the chemically tempered glass substrate, it is effective to reduce the stress generated at the sealing time. It is preferable to suppress the cracks and fractures of the chemically tempered glass substrate and the sealing layer 9. It is preferable to apply at least one of a structure [1] and a structure [2] illustrated below to reduce the stress generated at the sealing time.

[1] An electromagnetic wave absorbing material and a low-expansion filler are uniformly dispersed in the sealing layer 9.
[2] A film thickness of the sealing material layer 10 is made uniform, and a line width of the sealing layer 9 is made uniform based on the film thickness.

When inorganic fillers such as the electromagnetic absorbing material and the low-expansion filler are uniformly dispersed in the sealing layer 9, a thermal expansion coefficient of the sealing layer 9 is made uniform. Accordingly, it is possible to suppress a stress concentration caused by increasing of local thermal expansion difference between the glass substrates 2, 3 and the sealing layer 9, and the fractures and so on of the glass substrates 2, 3 and the sealing layer 9 based on the stress concentration. When the inorganic filler is aggregated, the thermal expansion difference between the aggregated part and a peripheral part thereof becomes large, and therefore, the stress concentration is easy to occur. Further, when the electromagnetic wave absorbing material is aggregated, the aggregated part is highly heated, and thereby, the stress concentration caused by the heat is easy to occur. The stress concentration part becomes a starting point of the fractures, and therefore, the fractures occur easily at the glass substrates and the sealing layer 9 by the stress generated at the sealing time. The electromagnetic wave absorbing material and the low-expansion filler are uniformly dispersed in the sealing layer 9, and thereby, it is possible to suppress the fractures caused by the stress concentration.

As for the structure [1], when the cross sections at 20 points of the sealing layer 9 are observed, it is preferable that a standard deviation of a total area ratio of the low-expansion filler and the electromagnetic wave absorbing material existing per a unit area of each of the cross sections is set to be 5% or less. A meaning of the standard deviation of the total area ratio of the low-expansion filler and the electromagnetic wave absorbing material being 5% or less is that the electromagnetic wave absorbing material and the low-expansion filler are uniformly dispersed in the sealing layer 9. Accordingly, it becomes possible to suppress the fractures and so on of the glass substrates and the sealing layer 9 caused by the stress concentration with high repeatability. It is more preferable that the standard deviation of the total area ratio of the low-expansion filler and the electromagnetic wave absorbing material to be set at 3% or less.

The structure [1] can be enabled by using, for example, a sealing material paste in which dispersibility of the electromagnetic wave absorbing material and the low-expansion filler is increased. The sealing material paste in which the dispersibility of the electromagnetic wave absorbing material and the low-expansion filler is increased can be obtained by applying methods as described below.

(1) A mixing condition of the sealing glass material and the vehicle is appropriately selected, and the dispersibility of the sealing glass material, in particular, of the electromagnetic wave absorbing material and the low-expansion filler relative to the vehicle is increased.
(2) A dispersing agent is used when the sealing glass material and the vehicle are mixed.
(3) Materials in which surface treatment is performed are used as respective composing materials (the sealing glass, the electromagnetic wave absorbing material, the low-expansion filler, and so on) of the sealing glass material.
(4) Materials of which specific surface areas are relatively small are used as the electromagnetic wave absorbing material and the low-expansion filler in the sealing glass material.

As for the method (1), it is preferable to select a condition capable of more increasing the dispersibility based on a mixing method of the sealing glass material and the vehicle. For example, when the sealing glass material and the vehicle are mixed by using a roll mill, it is possible to increase the dispersibility of the electromagnetic wave absorbing material and the low-expansion filler in the sealing material paste by increasing the number of times to pass over the roll mill (for example, five times or more). It is also the same as for cases when a mortar grinder, a planetary mixer, a bead mill, and so on are used, and it is possible to increase the dispersibility of the electromagnetic wave absorbing material and the low-expansion filler in the sealing material paste by setting conditions in accordance with using methods.

As for the method (2), dispersing agents such as an amine-based compound, a carboxylic acid-based compound, a phosphoric acid-based compound, and so on are used, and thereby, it is possible to increase the dispersibility of the electromagnetic wave absorbing material and the low-expansion filler in the sealing material paste. It is the same as for the method (3), and it is possible to increase the dispersibility in the sealing material paste by using the electromagnetic wave absorbing material and the low-expansion filler which are surface treated by the amine-based compound, the carboxylic acid-based compound, the phosphoric acid-based compound, and so on.

As for the method (4), a powder of which particle size is small is easy to be aggregated, and therefore, it is possible to increase the dispersibility of the electromagnetic wave absorbing material and the low-expansion filler in the sealing material paste by using a powder of which particle size is relatively large. Specifically, it is preferable to use the powder of which average particle size is within a range of 1 μm to 15 μm, and specific surface area is 4.5 m²/g or less. The electromagnetic wave absorbing material and the low-expansion filler in powder state as stated above are used, and thereby, it is possible to increase the dispersiblity in the sealing material paste.

The above-stated methods (1) to (4) may be used independently, or in combination. It is preferable to apply the two or more methods in combination from among the methods (1) to (4) to further increase the dispersibility of the electromagnetic wave absorbing material and the low-expansion filler in the sealing material paste. The dispersibilities of the electromagnetic wave absorbing material and the low-expansion filler in the sealing material paste are different depending on kinds and shapes thereof, a kind of the vehicle, and so on, and therefore, it is preferable that one or two or more methods selected from the methods (1) to (4) are appropriately selected in accordance with these conditions.

As for the structure [2], if variation exists in the film thickness of the sealing material layer 10, distortion and twist are easy to occur at the glass substrates 2, 3 when the electromagnetic wave 11 is irradiated thereto to melt and solidify the sealing material. High stress is generated by the distortion and twist of the glass substrates 2, 3, and the fractures and so on of the glass substrates and the sealing layer 9 are easy to occur. It is possible to suppress the distortion and twist of the glass substrates 2, 3 at the melting and solidifying time of the sealing material by making the film thickness of the sealing material layer 10 uniform to address to the above-stated problems. Further, it becomes possible to suppress the fractures and so on of the glass substrates and the sealing layer 9 based on the distortion and twist. A film thickness distribution of the sealing material layer 10 is represented as a line width distribution of the sealing layer 9 after the melting and solidification, and therefore, it is possible to suppress the fractures caused by the distortion and twist of the glass substrates 2, 3 by making the line width of the sealing layer 9 uniform.

As for the structure [2], it is preferable to set the film thickness distribution of the sealing material layer 10 within ±20% in surfaces of the glass substrates 2, 3. Further, it is preferable to set the line width distribution of the sealing layer 9 within ±20% in the surfaces of the glass substrates 2, 3 when the sealing layer 9 is planarly observed. The film thickness distribution of the sealing material layer 10 and the line width distribution of the sealing layer 9 are set to be within ±20%, and thereby, it is possible to suppress the fractures of the glass substrates 2, 3 and the sealing layer 9 with high repeatability. It is more preferable to set the film thickness distribution of the sealing material layer 10 within ±10%. It is more preferable to set the line width distribution of the sealing layer 9 within ±10%.

The film thickness distribution of the sealing material layer 10 is found as described below. At first, the film thicknesses of the sealing material layer 10 are measured at plural points (for example, 20 points). An average value (Have), a maximum value (Hmax), and a minimum value (Hmin) of the film thickness are found from these measurement values, and a maximum (+) and a minimum (−) of the film thickness distribution are found from expressions described below.

Film thickness distribution [maximum (+)]={(Hmax−Have)/Have}×100(%)

Film thickness distribution [minimum (−)]={(Hmin−Have)/Have}×100(%)

The line width distribution of the sealing layer 9 is the same, and the line widths of the sealing layer 9 are measured at plural points (for example, 20 points). An average value (Lave), a maximum value (Lmax), and a minimum value (Lmin) of the line width are found from these measurement values, and a maximum (+) and a minimum (−) of the line width distribution are found from expressions described below.

Line width distribution [maximum (+)]={(Lmax−Lave)/Lave}×100(%)

Line width distribution [minimum (−)]={(Lmin−Lave)/Lave}×100(%)

The structure [2] is enabled by appropriately selecting the conditions when, for example, the sealing material paste is coated. As for a coating method of the sealing material paste, it is preferable to apply the screen printing and the printing by the dispenser. When the screen printing is applied, it is possible to make the film thickness distribution of the sealing material layer 10 small by appropriately adjusting a printing pressure and a back pressure, a quality of material, hardness, and shape of squeegee, an angle of the squeegee relative to a screen plate, a sweep rate of the squeegee, a degree of parallelization between a printing substrate and the screen plate, a gap between the printing substrate and the screen plate, and a temperature of the printing substrate. When the printing by the dispenser is applied, it is possible to make the film thickness distribution of the sealing material layer 10 small by appropriately adjusting a scanning rate of a dispenser head, a gap between the printing substrate and the dispenser head, a jetting pressure and a temperature of the paste, a quality of material and shape of a needle, and a temperature of the printing substrate.

The structure [1] and the methods (1) to (4) enabling the structure [1], and the structure [2] and the methods enabling the structure [2] are effective when the chemically tempered glass having the CS value of 900 MPa or less and the CT value of 50 MPa or less is applied. Namely, it is possible to further improve the sealing property and the sealing reliability by the sealing glass material by reducing the stress generated at the sealing time in addition to controlling the surface compressive stress and the central tension stress of the chemically tempered glass. Besides, it is possible to obtain the sealing property and the sealing reliability with the glass package using the chemically tempered glass having high CS value and CT value by applying the structure [1] and the methods (1) to (4) enabling the same, and the structure [2] and the methods enabling the same depending on cases.

### EXAMPLES

Next, examples of the present invention and evaluation results thereof are described. Note that the following description is not intend to limit the present invention, and modifications are possible without departing from the spirit or essential characteristics thereof.

### Example 1

A bismuth-based glass frit (softening point: 410° C.) having a composition of Bi₂O₃: 83%, B₂O₃: 5%, ZnO: 11%, Al₂O₃: 1% in mass fraction, a cordierite powder of which average particle size (D50) is 4.3 μm, specific surface area is 1.6 m²/g as the low-expansion filler, and a laser absorbing material (electromagnetic wave absorbing material) having a composition of Fe₂O₃: 16.0%, MnO: 43.0%, CuO: 27.3%, Al₂O₃: 8.5%, SiO₂: 5.2% in mass fraction, and of which average particle size (D50) is 1.2 μm, specific surface area is 6.1 m²/g are prepared.

The average particles sizes (D50) of the cordierite powder and the laser absorbing material are measured by using a particle size analyzer (manufactured by Nikkiso Co., Ltd., device name: Microtrac HRA). The specific surface areas of the cordierite powder and the laser absorbing material are measured by using a BET specific surface area measurement device (manufactured by Mountech Co., Ltd., device name: Macsorb HM model-1201). Measurement conditions are as follows, absorbate: nitrogen, carrier gas: helium, measurement method: flow method (single point BET), deaeration temperature: 200° C., deaeration time: 20 minutes, deaeration pressure: N₂ gas flow/atmosphere, sample mass: 1 g. It is the same in the following examples.

The bismuth-based glass frit for 66.8 vol %, the cordierite powder for 32.2 vol %, and the laser absorbing material for 1.0 vol % are mixed and the sealing material (the thermal expansion coefficient (50° C. to 350° C.): 66×10⁻⁷/° C.) is manufactured. The sealing material for 83 mass % and a vehicle for 17 mass % manufactured by dissolving ethyl cellulose for 5 mass % into 2,2,4-trimethyl-1,3-pentanediol monoisobutyrate for 95 mass % as the binder component are mixed by using the roll mill to thereby prepare the sealing material paste.

Next, a soda-lime glass substrate (manufactured by Asahi Glass Co., Ltd., AS (thermal expansion coefficient: 85×10⁻⁷/° C.), size: 50×50×1.1 mmt) is prepared, and the sealing material paste is coated at a sealing region of the soda-lime glass substrate by the screen printing method. A screen plate of which mesh size is 325, and emulsion thickness is 20 μm is used for the screen printing. A pattern of the screen plate is a frame shape pattern of 30 mm×30 mm with a line width of 0.5 mm, and a radius of curvature R at a corner part is 2 mm. A coating layer of the sealing material paste is dried under a condition of 120° C.×10 minutes, and thereafter, it is baked under a condition of 480° C.×10 minutes, and the sealing material layer of which film thickness is 15 μm and line width is 0.5 mm is formed.

Next, a chemically tempered glass substrate (manufactured by Asahi Glass Co., Ltd., CS: 380 MPa, DOL: 10 μm, CT: 3.5 MPa, size: 50×50×1.1 mmt) is prepared, and this chemically tempered glass substrate and the soda-lime glass substrate having the sealing material layer are laminated. Next, a laser light (semiconductor laser) having a wavelength of 808 nm, spot diameter of 1.5 mm, power of 16.0 W (power density: 905 W/cm²) is irradiated on the sealing material layer through the soda-lime glass substrate at a scanning rate of 4 mm/sec under a state in which a pressure of 0.5 MPa is applied from above the soda-lime glass substrate, and the sealing material layer is melted, rapidly cooled and solidified to seal the chemically tempered glass substrate and the soda-lime glass substrate. An intensity distribution of the laser light is not constantly shaped but a laser light having an intensity distribution of an convex state is used. The spot diameter is set to be a radius of a contour line of which laser intensity becomes 1/e². The CS and the DOL of the chemically tempered glass substrate are measured by using a surface stress meter (manufactured by Orihara manufacturing Co., Ltd., device name: FSM-6000LE). The CT is calculated from the above-stated expression (1).

A heating temperature of the sealing material layer when the laser light is irradiated is measured by a radiation thermometer, then the temperature of the sealing material layer is 630° C. The softening point temperature T of the bismuth-based glass frit is 410° C., and therefore, the heating temperature of the sealing material layer corresponds to (T+220° C.). The states of the glass substrates and the sealing layer are observed after the laser sealing, and presence/absence of occurrences of the adhesive failure and fractures are checked. The sealing layer is observed by an optical microscope to measure the line width. Further, a thermal cycle test (one cycle: 90° C. to −40° C., 500 cycles) is performed to measure fracture occurrence rates (fracture occurrence rates of 100 pieces of packages after TCT) of the glass substrates and the sealing layer. These results are illustrated in Table 1. The line width of the sealing layer is illustrated as a relative value when the line width of the sealing material layer is set to be 100.

### Examples 2 to 5, Comparative Example 1

The chemically tempered glass substrate and the soda-lime glass substrates are laser sealed as same as the example 1 except that the chemically tempered glass substrates each having the sheet thickness, the CS, the DOL, the CT illustrated in Table 1 are used. The presence/absence of occurrences of the adhesive failure and fractures, the line width of the sealing layer, and the fracture occurrence rate after the thermal cycle test (TCT) after the laser sealing of respective examples are measured and evaluated as same as the example 1. These results are collectively illustrated in Table 1.

TABLE 1

| | | | | | Peel off | | |
|---|---|---|---|---|---|---|---|
| | Thickness of | | | | and | | |
| | Chemically Tempered | CS | | CT | Fracture at | Line | TCT Result |
| | Glass Substrate | Value | DOL | Value | Sealing | Width | (Fracture |
| | [mm] | [MPa] | [μm] | [MPa] | Time | [%] *1 | rate) [%] |
| Example 1 | 1.1 | 380 | 10 | 3.5 | None | 130 | 3 |
| Example 2 | 1.1 | 470 | 10 | 4.4 | None | 131 | 3 |
| Example 3 | 1.1 | 620 | 10 | 5.7 | None | 124 | 3 |
| Example 4 | 1.1 | 610 | 60 | 37.7 | None | 102 | 5 |
| Example 5 | 0.7 | 700 | 60 | 72.4 | None | 98 | 100 |
| Comparative | 0.7 | 1000 | 50 | 83.3 | Exist | 80 | (*2) |
| Example 1 | | | | | | | |

*1: A relative value when a line width before sealing is set to be 100.
(*2): Unable to perform the TCT test caused by the peel off, fracture at the sealing time.

As it is obvious from Table 1, the chemically tempered glass substrate of which CS is 900 MPa or less is used, and thereby, it is possible to increase the laser sealing property. It can be seen that the line width of the sealing layer is widen compared to the line width of the sealing material layer, and the wettability and reactivity of the sealing glass relative to the chemically tempered glass substrate are fine in each of the glass panels of the examples. Further, the chemically tempered glass substrate of which CT is 70 MPa or less is used, and thereby, it is possible to increase the reliability for the thermal cycle test (TCT) of the laser sealed glass panel.

### Example 6

The same bismuth-based glass frit, the cordierite powder, and the laser absorbing material as the example 1 are prepared. The bismuth-based glass frit for 66.8 vol %, the cordierite powder for 32.2 vol %, and the laser absorbing material for 1.0 vol % are mixed and the sealing material (the thermal expansion coefficient (50° C. to 350° C.): 66×10⁻⁷/° C.) is manufactured. The sealing material for 83 mass % is mixed with the vehicle for 17 mass % manufactured by dissolving ethyl cellulose for 5 mass % into 2,2,4-trimethyl-1,3-pentanediol monoisobutyrate for 95 mass % as the binder component. Next, the mixture is passed over a three roll mill for five times to enough disperse the cordierite powder and the laser absorbing material in the paste to thereby prepare the sealing material paste.

Next, the sealing material paste is coated at the sealing region of the soda-lime glass substrate (manufactured by Asahi Glass Co., Ltd., AS (thermal expansion coefficient: 85×10⁻⁷/° C.), size: 100×100×1.1 mmt) by the screen printing method. The screen plate of which mesh size is 325, and emulsion thickness is 20 μm is used for the screen printing. The pattern of the screen plate is the frame shape pattern of 70 mm×70 mm with the line width of 0.5 mm, and the radius of curvature R at the corner part is 2 mm. The coating layer of the sealing material paste is dried under the condition of 120° C.×10 minutes, and thereafter, it is baked under the condition of 480° C.×10 minutes, and the sealing material layer of which film thickness is 15 μm and line width is 0.5 mm is formed. The film thicknesses of the sealing material layer are measured at 20 points, the film thickness distribution in the substrate surface is found based on the above-stated method, then it is 15±3 μm (±20%).

Next, a chemically tempered glass substrate (manufactured by Asahi Glass Co., Ltd., the thermal expansion coefficient: 85×10⁻⁷/° C., CS: 560 MPa, DOL: 10 μm, size: 100×100×1.1 mmt) having a solar cell region (a region where a power generation layer is formed) is prepared, and this chemically tempered glass substrate and the soda-lime glass substrate having the sealing material layer are laminated. Next, the laser light (semiconductor laser) having the wavelength of 808 nm, the spot diameter of 1.5 mm, the power of 16.0 W (the power density: 905 W/cm²) is irradiated on the sealing material layer through the chemically tempered glass substrate at the scanning rate of 4 mm/sec under a state in which the pressure of 0.25 MPa is applied from above the chemically tempered glass substrate, and the sealing material layer is melted, rapidly cooled and solidified to seal the chemically tempered glass substrate and the soda-lime glass substrate. The intensity distribution of the laser light is not constantly shaped but the laser light having the intensity distribution of the convex state is used. The spot diameter is set to be the radius of the contour line of which laser intensity becomes 1/e².

The heating temperature of the sealing material layer when the laser light is irradiated is measured by the radiation thermometer, then the temperature of the sealing material layer is 630° C. The softening point temperature T of the bismuth-based glass frit is 410° C., and therefore, the heating temperature of the sealing material layer corresponds to (T+220° C.). The states of the glass substrates and the sealing layer are observed after the laser sealing, then the occurrences of the cracks and fractures are not recognized, and it is verified that the first glass substrate and the second glass substrate are finely sealed. Further, the sealing layer is observed by the optical microscope, the line widths are measured at 20 points, then the line width distribution of the sealing layer is 0.625±0.125 mm (±20%).

Next, a cross section of the sealing layer is observed as described below. At first, the laser sealed glass substrate is cut off by using a glass cutter and a glass pincher, and thereafter, embedded in an epoxy resin. After curing of the embedded resin is verified, it is roughly polished with a polishing paper of silicon carbide, and subsequently, the cross section of the sealing layer is mirror polished by using alumina particle dispersion liquid and diamond particle dispersion liquid. The cross section of the obtained sealing layer is carbon-deposited to make it an observation sample.

A reflected electron image observation of the cross section of the sealing layer is performed by using an analytical scanning electron microscope (manufactured by Hitachi High-Technologies corporation, SU6600). Observation conditions are as follows; acceleration voltage: 10 kV, electric current value setting: small, image capturing size: 1280×960 pixels, and file format of image data: Tagged Image File Format (tif). An image analysis of the reflected electron image of the photographed sealing layer cross section is performed by using a two-dimensional image analysis software (manufactured by Mitani corporation, WinROOF). A length per one pixel is found by using a scale of an electron micrograph, and calibration is performed. Subsequently, a part without any bubbles, scratches, stains of the sealing layer cross section is selected by a “rectangular ROI”, and thereafter, it is image processed by a 3×3 median filter to remove noises. Next, a region of the low-expansion filler and the laser absorbing material and a region of the sealing glass are sorted by using a “binarization by using two threshold values”. An upper limit threshold value is set to clearly distinguish between the region of the low-expansion filler and the laser absorbing material and the region of the sealing glass, and an area ratio of the low-expansion filler and the laser absorbing material is found. A lower limit threshold value is set at 0.000.

Measurements of a total area ratio of the low-expansion filler and the electromagnetic wave absorbing material existing per unit area of the cross section of the sealing layer are performed as for the cross sections at arbitrary 20 points. A standard deviation of the total area ratio of the low-expansion filler and the electromagnetic wave absorbing material is found from the measurement results at the 20 points of the cross section, then it is 4.8%. Manufacturing conditions of the glass package and the above-stated measurement results are illustrated in Table 2 together with results of the following examples and comparative examples.

### Example 7

When the sealing material paste is manufactured, the sealing material layer of which film thickness is 15 μm, line width is 0.5 mm is formed as same as the example 6 except that the mixture of the sealing material and the vehicle is passed over the three roll mill for seven times. The film thicknesses of the sealing material layer are measured as same as the example 6, then the film thickness distribution in the substrate surface is 15±1.2 μm (±8%).

Next, the sealing of the chemically tempered glass substrate and the soda-lime glass substrate by the laser light is performed as same as the example 6. The temperature of the sealing material layer when the laser light is irradiated is 630° C. as same as the example 6. A state of the glass package manufactured as stated above is observed, then the occurrences of cracks and fractures are not found at the glass substrates and the sealing layer, and it is verified to be well sealed. The line widths of the sealing layer are measured as same as the example 6, then the line width distribution of the sealing layer is 0.625±0.050 mm (±8%). Further, the observation of the cross sections at arbitrary 20 points of the sealing layer and the image analysis thereof are performed, then the standard deviation of the total area ratio of the low-expansion filler and the electromagnetic wave absorbing material is 2.6%.

### Example 8

When the sealing material paste is manufactured, the sealing material paste is prepared as same as the example 6 except that N-hydroxyethyl laurylamine (manufactured by NOF corporation, brand name: Nymine L-201) for 0.7 mass % is added to the mixture of the sealing material and the vehicle as the dispersing agent, and thereafter, it is passed over the three roll mill for three times. The sealing material layer of which film thickness is 15 μm, line width is 0.5 mm is formed as same as the example 6 by using the sealing material paste. The film thicknesses of the sealing material layer are measured as same as the example 6, then the film thickness distribution in the substrate surface is 15±1.4 μm (±9%).

Next, the sealing of the chemically tempered glass substrate and the soda-lime glass substrate by the laser light is performed as same as the example 6. The temperature of the sealing material layer when the laser light is irradiated is 630° C. as same as the example 6. A state of the glass package manufactured as stated above is observed, then the occurrences of cracks and fractures are not found at the glass substrates and the sealing layer, and it is verified to be well sealed. The line widths of the sealing layer are measured as same as the example 6, then the line width distribution of the sealing layer is 0.625±0.055 mm (approximately ±9%). Further, the observation of the cross sections at arbitrary 20 points of the sealing layer and the image analysis thereof are performed as same as the example 6, then the standard deviation of the total area ratio of the low-expansion filler and the electromagnetic wave absorbing material is 3.5%.

### Comparative Example 2

When the sealing material paste is manufactured, the sealing material layer of which film thickness is 15 μm, line width is 0.5 mm is formed as same as the example 6 except that the mixture of the sealing material and the vehicle is passed over the three roll mill for three times. The film thicknesses of the sealing material layer are measured as same as the example 6, then the film thickness distribution in the substrate surface is 15±1.2 μm (±8%).

Next, the sealing of the chemically tempered glass substrate and the soda-lime glass substrate by the laser light is performed as same as the example 6, then the fractures occur at the glass substrates at the laser sealing time, and it is impossible to seal between the glass substrates. The observation of the cross sections at arbitrary 20 points of the sealing layer and the image analysis thereof are performed as same as the example 6, then the standard deviation of the total area ratio of the low-expansion filler and the electromagnetic wave absorbing material is 8.0%. It is conceivable that it is incurred because the low-expansion filler and the electromagnetic wave absorbing material are not enough dispersed when the sealing material paste is manufactured.

### Comparative Example 3

When the sealing material paste is coated, the sealing material layer of which film thickness is 15 μm, line width is 0.5 mm is formed as same as the example 6 except that the conditions of the screen printing are changed. The film thicknesses of the sealing material layer are measured as same as the example 6, then the film thickness distribution in the substrate surface is 15±3.8 μm (approximately ±25%).

Next, the sealing of the chemically tempered glass substrate and the soda-lime glass substrate by the laser light is performed as same as the example 6, then the fractures occur at the glass substrates at the laser sealing time, and it is impossible to seal between the glass substrates. It is conceivable that it is incurred because a film thickness difference of the sealing material paste at the coating time is large, and distortion, twist, and so on are generated at the glass substrates at the laser sealing time. The observation of the cross sections at arbitrary 20 points of the sealing layer and the image analysis thereof are performed as same as the example 6, then the standard deviation of the total area ratio of the low-expansion filler and the electromagnetic wave absorbing material is 4.0%.

Measurement results of the examples 6 to 8, the comparative examples 2 to 3 are collectively illustrated in Table 2.

TABLE 2

| | | | | Comparative | Comparative |
|---|---|---|---|---|---|
| | Example 6 | Example 7 | Example 8 | Example 2 | Example 3 |
| Addition of | None | None | Exist | None | None |
| Dispersing Agent | | | | | |
| Number of Times of | 5 | 7 | 3 | 3 | 5 |
| Passing Over Roll | | | | | |
| Mill | | | | | |
| Film Thickness | 15 ± 3 | 15 ± 1.2 | 15 ± 1.4 | 15 ± 1.2 | 15 ± 3.8 |
| Distribution of | (±20%) | (±8%) | (±9%) | (±8%) | (±25%) |
| Sealing Material | | | | | |
| [μm] | | | | | |
| Line Width | 0.625 ± 0.125 | 0.625 ± 0.050 | 0.625 ± 0.055 | (Unable to | (Unable to |
| Distribution of | (±20%) | (±8%) | (±9%) | Measure) | Measure) |
| Sealing Layer [mm] | | | | | |
| Standard Deviation | 4.8 | 2.6 | 3.5 | 8.0 | 4.0 |
| of Area Ratio of | | | | | |
| Filler [%] | | | | | |
| Fracture of Glass | None | None | None | Exist | Exist |
| Substrate | | | | | |

*The standard deviation of the area ratio of the filler is the standard deviation of the total area ratio of the laser absorbing material and the low-expansion filler per unit area of the sealing layer.

An electronic device according to the present invention is effectively used for a solar cell, a flat panel display, and so on. A manufacturing method of an electronic device according to the present invention is effectively used for manufacturing of a solar cell, a flat panel display, and so on.

What is claimed is:

1. An electronic device, comprising:
a first glass substrate having a first surface including a first sealing region;
a second glass substrate having a second surface including a second sealing region corresponding to the first sealing region, and disposed with a predetermined gap above the first glass substrate such that the second surface faces the first surface;
an electronic element part provided between the first glass substrate and the second glass substrate; and
a sealing layer formed between the first sealing region of the first glass substrate and the second sealing region of the second glass substrate to seal the electronic element part, and made up of a molten fixed layer of a sealing glass material having an electromagnetic wave absorption ability,
wherein at least one of the first glass substrate and the second glass substrate is made up of a chemically tempered glass having a surface compressive stress value of 900 MPa or less.

2. The electronic device according to claim 1,
wherein a central tension stress value of the chemically tempered glass is 70 MPa or less.

3. The electronic device according to claim 1,
wherein the surface compressive stress value of the chemically tempered glass is in a range of 300 MPa or more and 900 MPa or less.

4. The electronic device according to claim 1,
wherein a thickness of the glass substrate made up of the chemically tempered glass is 4 mm or less.

5. The electronic device according to claim 1,
wherein the sealing glass material contains a sealing glass made up of a low-melting glass, an electromagnetic wave absorbing material of 0.1 vol % to 10 vol %, and a low-expansion filler of “0” (zero) vol % to 50 vol %.

6. The electronic device according to claim 5,
wherein a standard deviation of a total area ratio of the low-expansion filler and the electromagnetic wave absorbing material existing per unit area of each of cross sections is 5% or less when the cross sections at arbitrary 20 points of the sealing layer are observed.

7. The electronic device according to claim 5,
wherein a line width distribution of the sealing layer is within ±20% when the sealing layer is planarly observed.

8. The electronic device according to claim 5,
wherein the sealing glass is made up of a bismuth-based glass containing Bi₂O₃ for 70% to 90%, ZnO for 1% to 20%, and B₂O₃ for 2% to 12% in mass fraction.

9. The electronic device according to claim 1,
wherein the electronic element part includes a solar cell element.

10. A manufacturing method of an electronic device, comprising:
preparing a first glass substrate having a first surface including a first sealing region;
preparing a second glass substrate having a second surface including a second sealing region corresponding to the first sealing region and a sealing material layer formed on the second sealing region and made up of a baked layer of a sealing glass material having an electromagnetic wave absorption ability;
laminating the first glass substrate and the second glass substrate via the sealing material layer while facing the first surface and the second surface; and
forming a sealing layer sealing an electronic element part provided between the first glass substrate and the second glass substrate by irradiating an electromagnetic wave and locally heating the sealing material layer through the first glass substrate or the second glass substrate to melt and solidify the sealing material layer,
wherein at least one of the first glass substrate and the second glass substrate is made up of a chemically tempered glass having a surface compressive stress value of 900 MPa or less.

11. The manufacturing method of the electronic device according to claim 10,
wherein a central tension stress value of the chemically tempered glass is 70 MPa or less.

12. The manufacturing method of the electronic device according to claim 10,
wherein the surface compressive stress value of the chemically tempered glass is within a range of 300 MPa or more and 900 MPa or less.

13. The manufacturing method of the electronic device according to claim 10,
wherein a thickness of the glass substrate made up of the chemically tempered glass is 4 mm or less.

14. The manufacturing method of the electronic device according to claim 10,
wherein the preparing the second glass substrate comprises:
preparing a sealing material paste including a mixture of the sealing glass material containing: a sealing glass made up of a low-melting glass; an electromagnetic wave absorbing material of 0.1 vol % to 10 vol %; and a low-expansion filler of “0” (zero) vol % to 50 vol %, and a vehicle;
baking a coating layer formed by coating the sealing material paste at the second sealing region of the second glass substrate to form the sealing material layer.

15. The manufacturing method of the electronic device according to claim 14,
wherein a film thickness distribution of the sealing material layer in a surface of the glass substrate is within ±20%.

16. The manufacturing method of the electronic device according to claim 14,
wherein the electromagnetic wave absorbing material and the low-expansion filler are dispersed in the sealing material paste such that a standard deviation of a total area ratio of the low-expansion filler and the electromagnetic wave absorbing material existing per unit area of each of cross sections is 5% or less when the cross sections at arbitrary 20 points of the sealing layer are observed.

17. The manufacturing method of the electronic device according to claim 14,
wherein a laser light is irradiated while scanning along the sealing material layer as the electromagnetic wave.

18. The manufacturing method of the electronic device according to claim 10,
wherein the electronic element part includes a solar cell element.

19. A manufacturing method of an electronic device, comprising:
preparing a first glass substrate having a first surface including a first sealing region;
preparing a second glass substrate having a second surface including a second sealing region corresponding to the first sealing region;
preparing a sealing material paste including a mixture of a sealing glass material containing: a sealing glass made up of a low-melting glass; an electromagnetic wave absorbing material of 0.1 vol % to 10 vol %; and a low-expansion filler of “0” (zero) vol % to 50 vol %, and a vehicle;
baking a coating layer formed by coating the sealing material paste at the second sealing region of the second glass substrate to form the sealing material layer of which film thickness distribution is within ±20%;
laminating the first glass substrate and the second glass substrate via the sealing material layer while facing the first surface and the second surface; and
forming a sealing layer sealing an electronic element part provided between the first glass substrate and the second glass substrate by irradiating an electromagnetic wave and locally heating the sealing material layer through the first glass substrate or the second glass substrate to melt and solidify the sealing material layer,
wherein at least one of the first glass substrate and the second glass substrate is made up of a chemically tempered glass, and
wherein the sealing material paste in which the electromagnetic wave absorbing material and the low-expansion filler are uniformly dispersed is used such that a standard deviation of a total area ratio of the low-expansion filler and the electromagnetic wave absorbing material existing per unit area of each of cross sections is 5% or less when the cross sections at arbitrary 20 points of the sealing layer are observed.

20. The manufacturing method of the electronic device according to claim 19,
wherein a laser light is irradiated while scanning along the sealing material layer as the electromagnetic wave.
